(19) United States
(12) Patent Application Publication
(10) Pub. No.: US 2008/0286888 A1
(43) Pub. Date: Nov. 20, 2008

(54) TEST STRUCTURES AND METHODOLOGY FOR DETECTING HOT DEFECTS

(75) Inventors: Louis Lu-Chen Hsu, Fishkill, NY (US); Byeong Yeol Kim, Lagrangeville, NY (US); Xu Ouyang, Hopewell Junction, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/750,364

(22) Filed: May 18, 2007

(51) Int. Cl. H01L 21/66; H01L 23/58

(52) U.S. Cl. 438/18; 257/48; 257/E21.521; 257/E23.001

(57) ABSTRACT

Test structures for detecting defects arising from hybrid orientation technology (HOT) through detection of device leakage (gate leakage, junction leakage, and sub-threshold leakage), having at least one active region disposed in a re-grown region of a substrate: a layer of oxide; a layer of poly. Some test structures are dog-bone shaped test structure, tower shaped test structure, and inside-hole shaped. A method for detecting HOT defects involves measuring defect size and location in terms of device leakage, such as gate leakage, junction leakage, and sub-threshold leakage. HOT edge defect density and edge defect size distribution may be calculated, and the resulting defect information may be used to calibrate a defect yield model.

### FIELD OF THE INVENTION

The invention generally relates to the manufacture of semiconductor devices using hybrid orientation technology (HOT), and more particularly, to a monitoring system for detecting and characterizing various classes of defects, such as edge defects and corner defects, arising from HOT.

### BACKGROUND OF THE INVENTION

FETs (field effect transistors) are typically fabricated upon semiconductor wafers, such as Si (silicon) wafers, that have a single crystal orientation. In particular, most of today's semiconductor devices are built upon Si having a [100] crystal orientation. They may also be fabricated on an SOI (silicon on insulator) substrate. Other crystal orientations, such as [110] are also used.

Generally, FETs generally have two different polarities, either N-type or P-type, the resulting nomenclature being “NFET” and “PFET”, or variations thereof, respectively. These two polarity types are considered to be opposite to, or “complementary” of each other, giving rise to the nomenclature CMOS (complementary metal oxide semiconductor).

Generally, current in an FET flows in a “channel” between a “source” diffusion and a “drain” diffusion, and may be controlled be a gate voltage applied to a “gate” structure which is located above the channel. A “gate oxide” insulating layer is disposed between the gate and the channel. The source and drain elements are typically diffusions which are disposed within the surface of the substrate, the gate oxide is typically a very thin film disposed on the surface of the substrate, and the gate element typically comprises a conductive structure, such as polysilicon (poly).

Since NFETs and PFETs are often paired with each other in many circuits and devices, it is desirable to maintain balance in the operation of the NFETs and PFETs. It is also desirable to implement NFETs and PFETs with similar (if not identical) geometry and size.

Generally, NFETs depend on “electron mobility” in an inversion layer associated with the channel, and PFETs depend on “hole mobility” in the inversion layer. Generally, electrons may be considered to be the “opposite” of holes. Some materials behave as electron “donors” (readily giving up electrons), others behave as electron “acceptors” (readily accepting electrons).

Inversion layer electrons are known to have a high mobility for a [100] Si surface orientation, and inversion layer holes are known to have high mobility for a [110] surface orientation. Furthermore, hole mobility values on [100] Si are roughly 2-4 times lower than the corresponding electron mobility for the [100] crystallographic orientation. To compensate for this discrepancy, PFETs are typically designed with larger widths in order to balance pull-up currents against the NFET pull-down currents and achieve uniform circuit switching. NFETs having larger widths (to match the increased PFET width) are undesirable since they take up a significant amount of chip area.

On the other hand, hole mobilities on [110] Si are 2 times higher than on [100] Si; therefore, PFETs formed on a [110] surface will exhibit significantly higher drive currents than PFETs formed on a [100] surface. Unfortunately, electron mobilities on (110) Si surfaces are significantly degraded compared to [100] Si surfaces.

In response to the above-described disparities between electron and hole mobilities in a silicon substrate having a singe crystal orientation, semiconductor substrates have been formed having distinct regions with different crystal orientations that provide optimal performance for a specific N— or P-type device. For example, forming PFETs on a portion of the substrate having a [110] crystallographic surface, while forming NFET on another portion of the substrate having a [100] crystallographic surface. The nomenclature for this is “hybrid orientation technology”, abbreviated as “HOT”.

U.S. Pat. No. 6,995,456, incorporated by reference in its entirety herein, discloses an example of hybrid orientation technology (HOT). HOT means an integrated circuit structure that has a substrate having at least two types of crystalline orientations. The first-type transistors are on first portions of the substrate that have a first type of crystalline orientation and second-type transistors are on second portions of the substrate that have a second type of crystalline orientation. A straining layer is above the first-type transistors and the second-type transistors. Further, the straining layer can be strained above the first-type transistors and relaxed above the second-type transistors.

U.S. Pat. No. 6,815,278, incorporated by reference in its entirety herein, discloses ultra-thin silicon-on-insulator (SOI) and strained-silicon-direct-on-insulator with hybrid crystal orientations. Integrated semiconductor devices are formed upon an SOI substrate having different crystal orientations that provide optimal performance for a specific device. Specifically, an integrated semiconductor structure including at least an SOI substrate having a top semiconductor layer of a first crystallographic orientation and a semiconductor material of a second crystallographic orientation, wherein the semiconductor material is substantially coplanar and of substantially the same thickness as that of the top semiconductor layer and the first crystallographic orientation is different from the second crystallographic orientation is provided. The SOI substrate is formed by forming an opening into a structure that includes at least a first semiconductor layer and a second semiconductor layer that have different crystal orientations. The opening extends to the first semiconductor layer. A semiconductor material is epitaxial grown in the opening and then various etching and etch back processing steps are used in forming the SOI substrate.

An issue which is constantly confronting the integrated circuit (IC) designer is “scaling” or “scaleability.” Generally, “scaling” means the ability to shrink the geometry (size) of a device (such as an FET) while maintaining its functionality and performance characteristics. It can be appreciated that a simple conductive line can readily be scaled, and continue to function in its intended manner (up to inherent limits), but that scaling complex devices such as FETs presents more challenges.

As IC scaling (meaning, reduction in size) continues to progress, it becomes increasingly critical and challenging to maintain the performance scaling of MOS devices. As discussed above, hybrid orientation technology (HOT) takes advantage of the fact that pFET transistors operate best when fabricated on silicon with a [110] orientation, while nFET transistors operate best on silicon with a [100] orientation (the orientation of most substrates). For pFETs, hole mobility may be 2.5× higher on [110] surface orientation compared with that on a standard wafer with [100] surface orientation.

Hybrid orientation technology (HOT) has been described in the art, and is discussed hereinabove, with specific reference to U.S. Pat. Nos. 6,815,278 and 6,995,456. Neither of these patents addresses the specific classes of defects that arise due to the specific methods of fabricating hybrid orientation silicon substrates and how to detect, model, and reduce such defects during the mass manufacturing of such structures.

Most of the previously published methods of fabricating hybrid orientation substrates and those under developments today involve etching back portions of the silicon substrate and EPI (epitaxial, re-grown) region. However, data has shown that the re-grown region typically suffers from significantly increased defects. These defects typically extend from the interface between the two differently crystal-oriented substrates into the re-grown region, potentially cause “device leakages” which are harmful to the devices in the re-grown region.

As used herein, “device leakages” includes gate oxide leakage, junction leakage, and sub-threshold leakage. Gate oxide leakage is leakage current passing through the gate oxide layer. Junction leakage is leakage current passing through a reversely biased PN junction. Sub-threshold leakage is leakage current passing through the channel between a source and drain region when the device is turned off.

Hybrid orientation technology (HOT) is being researched extensively as the promising technology for 45 nm fabrication, and new defect types arise from process steps related to HOT which have different behavior than conventional random defects. These defects almost always happen at the edge of the EPI (epitaxial, re-grown) region, and they cannot be modeled by the conventional yield model.

What is needed is a methodology for detecting and monitoring defects particular to hybrid orientation technology (HOT).

### GLOSSARY

Unless otherwise noted, or as may be evident from the context of their usage, any terms, abbreviations, acronyms or scientific symbols and notations used herein are to be given their ordinary meaning in the technical discipline to which the disclosure most nearly pertains. The following terms, abbreviations and acronyms may be used throughout the descriptions presented herein and should generally be given the following meaning unless contradicted or elaborated upon by other descriptions set forth herein. Some of the terms set forth below may be registered trademarks (®).

Cell Well (CW) the cell well is an area in the silicon substrate that is prepared for functioning as a transistor or memory cell device by doping with an electron acceptor material such as boron or indium (p, electron acceptors or holes) or with an electron donor material such as phosphorous or arsenic (n, electron donors). The depth of a cell well is defined by the depth of the dopant distribution.

CMOS short for complementary metal oxide semiconductor. CMOS consists of n-channel and p-channel MOS transistors. Due to very low power consumption and dissipation as well minimization of the current in “off” state CMOS is a very effective device configuration for implementation of digital functions. CMOS is a key device in state-of-the-art silicon microelectronics.

crystal planes All lattice planes and lattice directions are described by a mathematical description known as a Miller Index. This allows the specification, investigation, and discussion of specific planes and directions of a crystal. In the cubic lattice system, the direction [hkl] defines a vector direction normal to surface of a particular plane or facet. The Miller Indices h,k,l for a diamond unit cell (silicon has the diamond structure) are [100], [110] and [111].

dopant element introduced into semiconductor to establish either p-type (acceptors) or n-type (donors) conductivity. Common dopants are,
p-type: boron (B), Indium (In)
n-type: phosphorous (P), arsenic (As), antimony (Sb)

electrons Generally speaking, electrons are subatomic particles orbiting the nucleus of an atom in valence bands, and contribute to the electrical conductivity of a semiconductor material. see holes.

FET short for field effect transistor. The FET is a transistor that relies on an electric field to control the shape and hence the conductivity of a “channel” in a semiconductor material. FETs are sometimes used as voltage-controlled resistors. The terminals of FETs are called gate, drain and source.

holes Generally speaking, a “hole” is a vacancy in the electron population of a valence band—in other words, a missing electron—and contributes to the conduction of a semiconductor material. see electrons.

MOS short for metal oxide semiconductor.

MOSFET short for metal oxide semiconductor field-effect transistor. MOSFET is by far the most common field-effect transistor in both digital and analog circuits. The MOSFET is composed of a channel of n-type or p-type semiconductor material, and is accordingly called an NMOSFET or a PMOSFET. (The ‘metal’ in the name is an anachronism from early chips where gates were metal; modern chips use polysilicon gates, but are still called MOSFETs).

n-type semiconductor in which concentration of electrons is higher than the concentration of “holes”. See p-type.

p-type semiconductor in which concentration of “holes” is higher than the concentration of electrons. See n-type.

semiconductor Generally, any of various solid crystalline substances, such as germanium or silicon, having conductivity greater than an insulator, but less than god conductors, and used especially as a base material for computer chips and other electronic devices. Semiconductor material doped with valence +3 acceptor impurities (these materials—such as boron aluminum indium and gallium—add holes to the semiconductor material) is termed “p-type”. Semiconductor material doped with valence +5 donor material (these materials—such as arsenic, antimony and phosphorous—add electrons to the semiconductor material) is termed “n-type”.

Si Silicon, a semiconductor material.

STI short for shallow trench isolation. STI is used for transistor isolation, in CMOS.

Units of Length Various units of length may be used herein, as follows:

meter (m) A meter is the SI unit of length, slightly longer than a yard.
1 meter=˜39 inches. 1 kilometer (km)=1000 meters=˜0.6 miles. 1,000,000 microns=1 meter. 1,000 millimeters (mm)=1 meter.
100 centimeters (cm)=1 meter.

micron (μm) one millionth of a meter (0.000001 meter); also referred to as a micrometer. may be written as “um”, rather than “μm”.

mil 1/1000 or 0.001 of an inch; 1 mil=25.4 microns.

nanometer (nm) one billionth of a meter (0.000000001 meter).

Angstrom (\acute{Å}) one tenth of a billionth of a meter. 10 \acute{Å}=1 nm.

### SUMMARY OF THE INVENTION

It is an aspect of the invention to provide improved techniques for implementing hybrid orientation technology (HOT) substrates, and devices formed on the substrates, by detecting, characterizing and accommodating defects arising from HOT.

It is another aspect of the invention to provide on-wafer test structures capable of detecting defects arising from hybrid orientation technology through detection of various leakages caused by such defects.

It is another aspect of the invention to separately detect and quantify increased defect originates from corner of the re-grown substrate, and separate its impact from defect originates from edge of the re-grown substrate, by using the dog-bone shaped test structures.

It is another aspect of the invention to measure edge defects with varying sizes and compute defect size distribution through uniquely designed test structures and yield model.

It is another aspect of the invention to provide fair and side-by-side comparison among devices located at varying distance from the edge of re-grown substrate, and use this data to help determine design rules of transistor placements, by using the tower shaped test structures.

It is another aspect of the invention to provide a monitoring system of junction leakage induced by such defects by uniquely designed inside-hole structures to maximize the interface perimeter and reduce series resistance to allow junction leakage detection.

According to the invention, various test structures are designed and fabricated in wafers for detecting and monitoring edge defects in a HOT semiconductor substrate.

The HOT semiconductor substrate is defined as a semiconductor substrate, typically silicon, or silicon on insulator (SOI), having two regions with different crystalline structure. For example, a bulk region with [110] crystalline structure (well adapted for PFETs, with favorable hole mobility) and a re-grown region with [100] crystalline structure (well adapted for NFETs, with favorable electron mobility), or, vice-versa, a bulk region with [100] crystalline structure and a re-grown region with [110] crystalline structure.

Generally, the edge defects propagate from a common edge of the two regions, into the re-grown region, and are known to cause “device leakage” (leakage in devices fabricated in areas having defects) including, but not limited to gate leakage, junction leakage, and sub-threshold leakage.

Two of the test structures disclosed herein are elongate—a dog-bone shaped test structure (FIG. 4A) and a tower-shaped test structure (FIG. 8).

A dog-bone shaped test structure (FIG. 4A) has an elongate active region (or area) in a larger, elongate re-grown region. The re-grown region has enlarged, rounded ends (giving it a dog-bone shape) to substantially reduce (such as eliminate) corner effects so that edge effects can better be detected. A layer of oxide is disposed over the substrate, and layer of polysilicon (poly) is disposed over the oxide, at least atop the active region, and may cover the entire test structure. A non-HOT reference structure (FIG. 4B) with a substantially identical active region is used for subtracting normal leakage. This test structure is intended for detecting gate oxide leakage.

A test structure (FIG. 6) similar to the dog-bone shaped test structure, but wherein the re-grown region does not have enlarged, rounded ends, and is sensitive to both edge effects and corner effects. By comparison between the measurements of structures in FIG. 4A and FIG. 6, the impact due to corner-intensive HOT defects can be separately detected. This test structure is intended for detecting gate oxide leakage.

A tower-shaped test structure (FIG. 8) has an active region in a re-grown region. The re-grown region has a plurality (n) of portions, each portion has a different width. This test structure is intended for detecting gate oxide leakage.

An inside-hole shaped test structure (FIG. 9) has a pad of re-grown region as the substrate; a plurality of openings extending through the re-grown region, exposing underlying silicon; an active region formed within the re-grown region; and a plurality of openings extending through the active region, exposing the underlying re-grown region, and is intended for detecting junction leakage.

A structure specific to using sub-threshold leakage to detect HOT defects is not discussed herein because it is believed that there are many other mechanisms that can cause sub-threshold leakage, and sub-threshold leakage is also sensitive to device parameters such as implants. Therefore it appears that sub-threshold leakage would not be as good of a method for HOT defect detection as gate leakage and junction leakage. However, sub-threshold leakage may be used in ways similar to those disclosed herein for HOT defect detection. For detecting sub-threshold leakage, two active regions (rather than one), with a channel therebetween, may be required.

According to the invention, a method for detecting defects arise from hybrid orientation technology (HOT) comprises measuring defect size and location in terms of device leakage, such as gate leakage, junction leakage, and sub-threshold leakage. Based on dimensions of test structures used to collect the leakage data, HOT edge defect density and edge defect size distribution may be calculated, and the resulting defect information may be used to calibrate a defect yield model.

According to the invention, a method for detecting defects in a hybrid orientation technology (HOT) substrate, comprises: fabricating test structures for detecting edge defects in a HOT semiconductor substrate; wherein the test structures are selected from the group consisting of dog-bone shaped test structure, tower shaped test structure, and inside-hole shaped test structure.

The test structures may comprise dog-bone shaped, and facilitate separation of the effects of defects originating from the edge and corner of the re-grown region.

The test structures may comprise tower shaped and can detect HOT defects of varying sizes arising from a single piece of re-grown region.

The test structures generally comprise active regions disposed in re-grown regions; an overlying poly layer: and oxide disposed between the poly and the active regions.

A distance (d) between an edge of the active region and an edge of the re-grown region may be substantially uniform along an edge of a given test structure.

The test structures may comprise inside holes that can detect detects junction leakage induced by HOT defects while reducing the series resistance of the current path.

According to the invention, test structures for detecting defects arising from hybrid orientation technology (HOT) through detection of device leakage caused by such defects, comprise: at least one active region disposed in a re-grown region of a substrate: a layer of oxide disposed on a surface of the substrate; and a layer of polysilicon disposed over the oxide, at least atop the active region. Device leakage may be selected from the group consisting of gate leakage, junction leakage, and sub-threshold leakage. The test structures may be selected from the group consisting of dog-bone shaped test structure, tower shaped test structure, and inside-hole shaped test structure. Reference test structures may also be included.

### BRIEF DESCRIPTION OF THE DRAWINGS

Reference will be made in detail to embodiments of the disclosure, examples of which may be illustrated in the accompanying drawing figures (FIGs). The figures are intended to be illustrative, not limiting. Although the invention is generally described in the context of these embodiments, it should be understood that it is not intended to limit the invention to these particular embodiments.

Certain elements in selected ones of the figures may be illustrated not-to-scale, for illustrative clarity. The cross-sectional views, if any, presented herein may be in the form of “slices”, or “near-sighted” cross-sectional views, omitting certain background lines which would otherwise be visible in a true cross-sectional view, for illustrative clarity. In some cases, hidden lines may be drawn as dashed lines (this is conventional), but in other cases they may be drawn as solid lines.

If shading or cross-hatching is used, it is intended to be of use in distinguishing one element from another (such as a cross-hatched element from a neighboring un-shaded element. It should be understood that it is not intended to limit the disclosure due to shading or cross-hatching in the drawing figures.

Elements of the figures may (or may not) be numbered as follows. The most significant digits (hundreds) of the reference number correspond to the figure number. For example, elements of FIG. 1 are typically numbered in the range of 100-199, and elements of FIG. 2 are typically numbered in the range of 200-299. Similar elements throughout the figures may be referred to by similar reference numerals. For example, the element 199 in FIG. 1 may be similar (and possibly identical) to the element 299 in FIG. 2. Throughout the figures, each of a plurality of elements 199 may be referred to individually as 199a, 199b, 199c, etc. Such relationships, if any, between similar elements in the same or different figures will become apparent throughout the specification, including, if applicable, in the claims and abstract.

FIGS. 1A and 1B are photomicrographs showing two typical classes of defects arising from hybrid orientation technology (HOT), according to the prior art.

FIG. 2A is a top view diagram of an EPI (epitaxial) region 202 including an active region 204, a poly structure 206 and an edge defect 208, according to the prior art.

FIG. 2B is a graph illustrating the critical length concept, according to the prior art.

FIG. 3 is a flowchart showing data collected using various test structures and related yield model to compute defect density and defect size distribution, according to the invention.

FIG. 4A is a plan view diagram of a dog-bone shaped test structure, with HOT, to detect edge defects originating from the edge of the re-grown region, according to the invention.

FIG. 4B is a plan view diagram of a test structure, without HOT, used in conjunction with the FIG. 4A dog-bone shaped test structure, according to the invention.

FIG. 5 is a cross-sectional diagram of the dog-bone shaped test structure of FIG. 4A, according to the invention.

FIG. 6 is a diagram showing a test structure which is sensitive to defects originating from a corner of the re-grown region, according to the invention.

FIG. 7 is a graph showing how a dog-bone shaped structure measures the defect size distribution for defect size greater than the designed dimension, according to the invention.

FIG. 8 is a plan view diagram of a tower shaped test structure, according to the invention.

FIG. 9 is a graph showing how the tower shaped structure simultaneously measures the defect size distribution at multiple designed dimensions, according to the invention.

FIG. 10 is a top view diagram showing inside-hole shaped test structures, according to the invention.

### DETAILED DESCRIPTION OF THE INVENTION

Throughout the descriptions set forth herein, lowercase numbers or letters may be used, instead of subscripts. For example Vg could be written V_{g}. Generally, lowercase is preferred to maintain uniform font size.) Regarding the use of subscripts (in the drawings, as well as throughout the text of this document), sometimes a character (letter or numeral) is written as a subscript—smaller, and lower than the character (typically a letter) preceding it, such as “Vₛ” (source voltage) or “H₂O” (water). For consistency of font size, such acronyms may be written in regular font, without subscripting, using uppercase and lowercase—for example “Vs” and “H20”.

Although various features of the invention may be described in the context of a single embodiment, the features may also be provided separately or in any suitable combination. Conversely, although the invention may be described herein in the context of separate embodiments for clarity, the invention may also be implemented in a single embodiment. Furthermore, it should be understood that the invention can be carried out or practiced in various ways, and that the invention can be implemented in embodiments other than the exemplary ones described hereinbelow. The descriptions, examples, methods and materials presented in the in the description, as well as in the claims, should not be construed as limiting, but rather as illustrative.

If any dimensions are set forth herein, they should be construed in the context of providing some scale to and relationship between elements. For example, a given element may have an equal, lesser or greater dimension (such as thickness) than another element. Any dimensions or relationships that are important or critical will generally be identified as such. The term “at least” includes equal to or greater than. The term “up to” includes less than. If any ranges are set forth herein, such as 1-10 microns, sub-ranges are implied, if not expressly set forth, such as 1-5 microns, 6-10 microns, 3-8 microns, 4-6 microns, etc. Also, an open-ended range or ratio such as “at least 2:1”, should be interpreted to include sub-ranges such as at least 3:1, at least 5:1, and at least 10:1.

As mentioned above, the implementation of hybrid orientation technology (HOT) has resulted in new defect types, typically occurring at the edge of the EPI (epitaxial, re-grown) region. For example, portions of a [100] crystal orientation substrate may be etched back, and [110] crystal orientation silicon may be epitaxially (EPI) re-grown in these regions. Generally, the [100] regions are preferable for the fabrication of NFETs, and the [110] regions are preferred for the fabrication of PFETs. Defects will tend to manifest themselves at the interface (edge) of these two regions, and in particular, extending into the re-grown (EPI) region.

Semiconductor substrates (such as SOI) formed using HOT may exhibit defects, particularly at the borders (interfaces, edges) of adjacent areas (regions) of the two different crystalline structures implemented on the substrate. Various test structures and methodologies for detecting HOT defects are described hereinbelow.

As used herein, there are
two conductivity types of interest (for FETs), “n” and “p”,
two crystalline structures of interest, “[100]” and “[110]”, and
two current mechanisms of interest, “electrons” and “holes”, which are usually associated (in HOT) as follows.
NFET, [100], electron donors (“electrons”)
PFET, [110], electron acceptors (“holes”)

According to the invention, generally, a yield model based on critical length along the EPI edge, instead of conventional critical area is disclosed. New test structures are designed to measure and extract edge defect density and size distribution from test wafers by utilizing this yield model.

New test structures using gate leakage and junction leakage to detect EPI edge defects from HOT process, and therefore guide process improvement, further allows to extract defect density and size distribution which are required to better model the yield impact of these defects. This allows someone to make important business and technical decisions with accurate yield prediction, and optimize development resources based on yield assessment.

### HOT Edge Defects

Edge defects have been found to cause significant gate leakage in wafers fabricated by HOT. These defects could also cause junction leakage. Two major defect types have been observed—“V-shaped” and “line” defects.

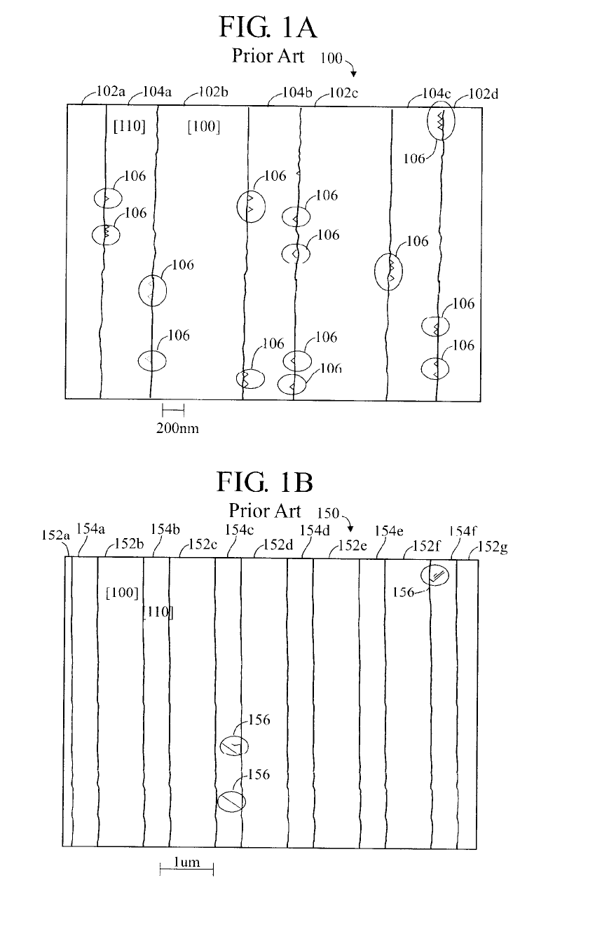

FIGS. 1A and 1B, illustrate two types of associated with the interface (at the edge, or border of) HOT regions having different crystalline structure, and which may be characterized using the techniques disclosed herein.

FIG. 1A illustrates an area 100 of a semiconductor substrate approximately 4000 nm (400 um) wide, and having alternating regions (areas, stripes) 102a, 104a, 102b, 104b, 102c, 104c, 102d of silicon having [100] crystal orientation and [110] crystal orientation, upon which semiconductor devices, such as NFETs and PFETs (as well as other elements such as isolation trenches, conductive lines, etc.) may be formed, respectively. The scale in this figure is indicated by the hash marks indicating 200 nm. As shown herein, the substrate exhibits V-shaped defects 106, extending into the 104 stripes, from their edges (borders, interfaces with adjacent 102 stripes).

Generally, by way of example, the 102 stripes are silicon having [100] crystal orientation and are best suited for NFETs, and the 104 stripes are silicon having [110] crystal orientation and are best suited for PFETs.

FIG. 1B illustrates an area 150 of a semiconductor substrate approximately 7 um wide, and having alternating regions 152a, 154a, 152b, 154b, 152c, 154c, 152d, 154d, 152e, 154e, 152f, 154f, 152g of silicon having [100] crystal orientation and [110] crystal orientation, upon which semiconductor devices, such as NFETs and PFETs may be formed. The scale in this figure is indicated by the hash marks indicating 1 um. As shown herein, the substrate exhibits line defects 156, extending into the 144 stripes, from their edges where the transition to the [100] crystal orientation is made

With regard to FIGS. 1A and 1B, by way of example, the [110] crystal orientation regions may be “bulk” (native to the wafer), and the [100] crystal orientation regions may be SOI, re-grown, EPI, or vice-versa. It should be understood that the invention is intended to be illustrated by this example, and not to be limited by it.

These edge defects (106, 156) have been found to cause significant gate leakage in wafers fabricated by HOT, as compared with devices fabricated without hybrid orientation technology. These defects could also cause junction leakage, as well as sub-threshold leakage.

### Detecting and Characterizing the Defects

According to the invention, generally, it is desirable to detect and characterize (quantify) defects specific to HOT, such as V-shaped and line defects, and alter design and fabrication accordingly, such as to increase performance and yield.

Generally, three different test structures for HOT defect detection will be described, hereinbelow, as follows:
dog-bone shaped test
tower shaped test structure
inside-hole shaped

Each test structure differs from the other in their design and purpose.

### Critical Length Concept

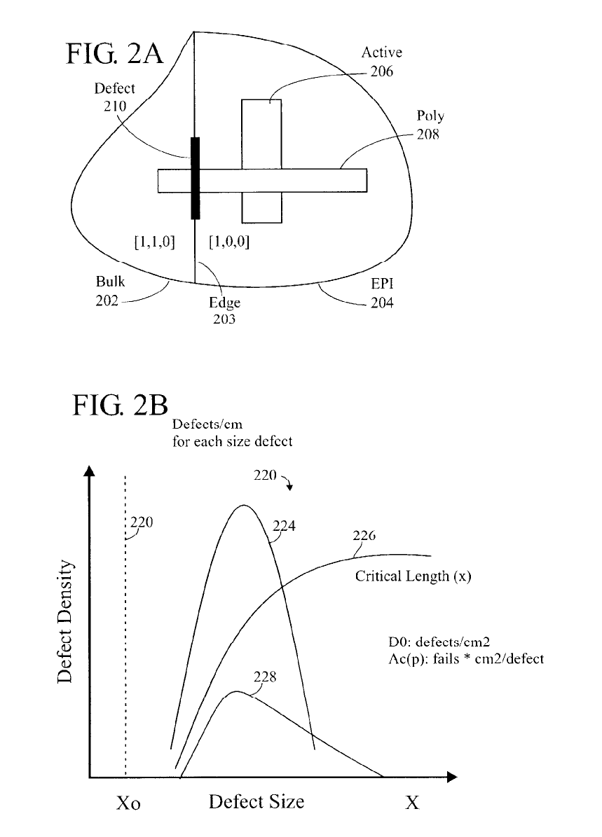

Before discussing the test structures, it is important to understand the “critical length concept”, which is illustrated in FIGS. 2A and 2B.

FIG. 2A illustrates a semiconductor substrate 200. A first portion 202 (compare 102) of the substrate 200 may be “bulk” silicon having a first crystal orientation, such as [110]. Another portion 204 of the substrate 200 may be epitaxial (EPI) region 204 (compare 104) which is re-grown, having a second crystal orientation [100] different than the first crystal orientation, such as [100]. The second portion 204 shares an edge (interface) 203 with the first portion.

An active region 206 is shown, formed within the epitaxial region 204. The active region 206 corresponds to, and for test purposes functions analogous to, a source or drain diffusion in an FET.

A poly region 208 extends from within the region 204, across an edge of the region 204, into the region 202. The poly structure 208 intersects the active region 206, and corresponds to, and for test purposes functions analogous to, a gate of an FET. A thin layer of oxide (not shown) may be disposed on the surface of the substrate so as to be between the active region 204 and the poly structure 208, analogous to a gate oxide of an FET. The poly 208 crossing the active region 206 is representative of a transistor (such as FET) region, and can be used to measure device leakage, such as gate oxide leakage.

An edge defect 210 is shown on the left-hand edge (as viewed) of the EPI region 204. Not all EPI edge defects will cause electrical failures. Here it is assumed that only defects that touch the transistor region (206/208) will cause failures. In FIG. 2A, the edge defect 208 is illustrated crossing the poly 206. The suspected major failure mechanism is increased gate leakage.

As used herein, “critical length” is defined as the length along the EPI edge where a defect will cause an electrical failure. Understandably, critical length is dependent on defect size, each fixed defect size has a corresponding critical length from layout.

FIG. 2B is a graph 220 illustrating the critical length concept. The horizontal axis is defect size (X). The vertical axis is defect density.

The dashed vertical line 222 at (Xo) represents the minimum size of defect that can possibly reach a transistor.

The line 224 represents defects/cm for each size defect.

The line 226 represents critical length (x).

The area under the line 228 represents,

Do: defects/cm²

Ac(p): fails*cm²/defect

Assuming defect density (defects/cm) for a defect with size of x (defect size distribution) is DSD(x)/cm, where x is the defect size.

Critical length for defect size x is d(x) cm.

The expected number of “killer” defects is given by the formula

$$λ = {\int }_{Xo}^{x max} DSD ( x ) \cdot d ( x ) d x$$

and the yield is exp (−λ).

### Using Test Structures to Measure Defect Size

Before discussing the specific test structures, it is useful to examine the methodology used herein, generally, to characterize defects.

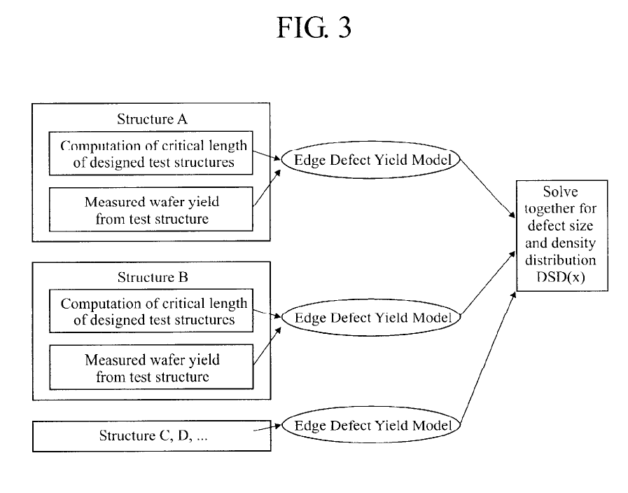

FIG. 3 is a flowchart illustrating the methodology. For each of a number of test structures (A,B,C,D, . . . ) critical length is computed for the designed test structure, and wafer yield is measured from the test structure. Each test structure (A,B,C,D, . . . ) is designed to be sensitive to certain defect sizes. Wafer yield is an actual measurement taken from wafers having the test structure(s).

For each test structure (A,B,C,D, . . . ) the critical length computation and the wafer yield measurement is provided to an edge defect yield model. The results of the yield models for each of the test structures is combined, to solve together for defect size and density distribution DSD(x).

### Test Structure 1: Dog-Bone Shaped Test Structure:

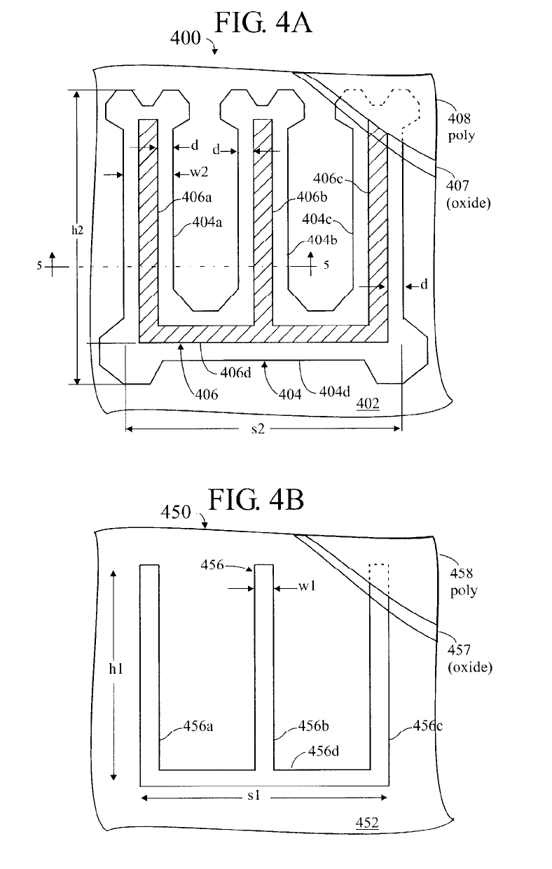

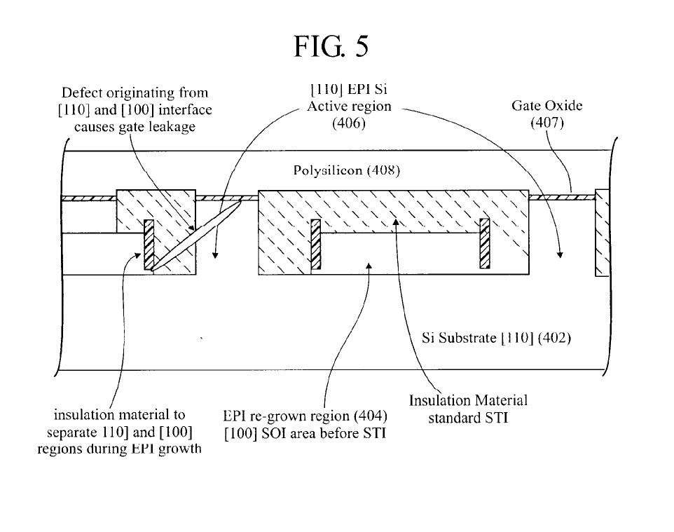

FIG. 4A (plan view) and FIG. 5 (cross-sectional view) illustrate a dog-bone shaped test structure and methodology. Generally, the dog-bone shaped test structure is used to detect HOT defects originating from the edges of the re-grown region. The dog-bone shape is intended to detect gate oxide leakage defects, and has corner treatment (rounded corners) to minimize sensitivity to corner defects and allow maximum sensitivity to edge defects. (The rounded dog-bone corners are shown polygonal.)

As used herein, “dog-bone shaped” means an elongate structure having a length substantially greater (such as at least 2 or 3 times greater) than its width, and two opposite ends, at least one of which has an enlarged width, or a bulbous end. The name comes from the shape of elongate bones, such as a mammal's tibia (shinbone), fibula (calf bone), or femur (thigh bone). Dog biscuits are often patterned after this shape (but with more symmetry). Idealized dog-bones may also be seen in the skull- and cross bones image displayed by on the “Jolly Roger” (the traditional skull and cross-bone flag of European and American pirates).

FIG. 4A shows a HOT structure 400 for measuring gate leakage caused by HOT defects.

FIG. 4B is a non-HOT reference (“control”) structure 450 which may be fabricated on the same wafer, side-by-side with the FIG. 4A HOT structure, to subtract out (eliminate any effect from) normal gate leakage.

In FIG. 4A, an active region 406 (compare 206) is shown. The active region 406 is drawn with shading (cross-hatching) for illustrative clarity, but it should be understood that FIG. 4A is not a cross-section, but rather a plan, top view. The active region 406 comprises three elongate active areas 406a, 406b, 406c which are substantially the same size as one another, and parallel with one another. The top ends of the three active areas 406a, 406b, 406c are vertically aligned with one another. The bottom ends of the three active areas 406a, 406b, 406c are joined by another elongate active region 406d which is generally perpendicular to the three active areas 406a, 406b, 406c. In aggregate, the active region 406 (comprising 406a, 406b, 406c, 406d) is in the shape of an “E” (on its side), or a “comb” having three “tines”.

FIG. 4B illustrates an active region 456 substantially identical to the active region 406, having three elongate active areas 456a, 456b, 456c joined at one end by a fourth active region 456d.

As best viewed in FIG. 4B, typical (exemplary) dimensions for the active areas (404, 454) are:
w1, width of the three active areas (406a/456a, 406b/456b, 406c/456c), 100 nm.
h1, length of the three active areas (406a/456a, 406b/456b, 406c/456c), 10 μm.
s1, length of the active region (e.g., 406d, 456d), 100 μm

The test structure of FIG. 4A differs from the reference (control) structure of FIG. 4B in that the test structure of FIG. 4A has a re-grown region 404 (compare 204) surrounding the active region 406. The active region 406 is formed as a diffusion (analogous to a source or drain of an FET) within the re-grown region 404 so that it is fully surrounded by the re-grown region 404 which, in turn is surrounded by bulk silicon 402 (compare 202). In FIG. 4B, the active region 456 is formed as a diffusion within conventional, bulk silicon 452.

The re-grown region 404 is essentially uniformly larger (wider and longer) than the active region 406, and is also in the shape of an “E” (on its side), or a “comb” having three elongate regions 404a, 404b and 404c joined at one end by a fourth region 404d. Each of the four active regions 406a, 406b, 406c, 406d are positioned substantially symmetrically within a corresponding on of the four re-grown regions 404a, 404b, 404c, 404d.

As best viewed in FIG. 4a, typical (exemplary) dimensions for the re-grown region 404 are:
w2, width of the three re-grown areas (404a, 404b, 404c) 200 nm.
h1, length of the three re-grown areas (404a, 404b, 404c), 100 μm.
s1, length of the active region (404d), 100 μm.

An oxide layer 407 (shown partially, for illustrative clarity) is disposed over the surface of the substrate 402, and layer of polysilicon 408 (shown partially, for illustrative clarity) is disposed over the oxide layer 407. The test structure 400 can function analogous to an FET, and be used to measure gate oxide leakage resulting from edge defects (compare 210).

It should be understood that is only necessary that the oxide 407 and poly 408 cover the active regions 406, but they may readily be disposed over the entire area of the test structure 400, for simplicity. Also, the poly 408 may extend to a conventional pad (not shown) for electrical probing by an external test instrument (not shown) when making measurements. Similar layers of oxide 457 and poly 458 are shown in FIG. 4B, the “reference” structure.

Regarding the test structure 400, a critical dimension is the distance between an edge of an the active region 406 and an edge of the re-grown region 404. This designed distance is labeled “d”, at various places in FIG. 4A. Note that this distance “d” is measured along the main length of the three elongate active areas 406a,406b,406c, and not at their ends. This distance “d” is designed to be substantially uniform (constant, not varying) along the length of the three elongate active areas 406a,406b,406c, on both sides of the three elongate active areas 406a,406b,406c.

A typical (exemplary) dimension for the designed distance “d” is 50-100 nm.

Corners of the re-grown region 404 are enlarged and rounded (bulbous), to reduce the impact of corner edge defects. Because the distance between edges of the active region 406 and edges of the re-grown region 404 is substantially larger at the corners (extremities) than along the length of the elongate active areas and elongate re-grown region, this reduces the impact of corner edge defects, so that the edge defects of interest will have the dominant effect upon the test structure.

The enlarged corners of the re-grown region 404 give rise to the name “dog-bone” shaped, and it can be seen that there are three dog-boned shaped test structures in FIG. 4A, joined at their bottom ends. (Hence, the bottom ends of each dog-bone structure do not appear distinctly in the figure.) In practice, the test structure may comprise many (more than three) of these dog-bone structures (long structure with many comb teeth) in order to increase the detection area.

The test structure of FIG. 4A is intended to detect critical leakage, in this case gate leakage, with corner treatment to allow maximum sensitivity to edge defects.

Gate oxide (not shown in FIG. 4A, see FIG. 5) is disposed between the active region 406 and the polysilicon 408. The active region 406, gate oxide, and poly 408 simulate an FET, for testing purposes.

During testing, the leakage current between the poly 408 and the active region 406 is measured. If there is a defect originating from the edge of the re-grown region 404 and extends into the active region 406, it will cause gate leakage and therefore be detected.

As a reference, the test structure shown in FIG. 4B has exactly the same shape as the active region 406 shown in FIG. 4A. However, it does not have the re-grown region 404. Therefore, the gate leakage due to HOT defects will be equal to the gate leakage measured by structure in FIG. 4A subtracted by the normal gate leakage measured by structure in FIG. 4B.

Because it is expected that concaved corners (<90°) of the re-grown region generate more defects than straight edges (180°), the corners of the re-grown region is treated as in FIG. 4A to reduce the impact of defects originating from corners. This gives the test structure its dog-bone shape.

The corners of the dog-bone structures are shown in FIG. 4A as being polygonal (generally octagonal), rather than rounded. The ends could be rounded, but many design rules restrict the use of circular patterns, and only allow horizontal and vertical lines and 45 degree lines. In either case (polygonal or rounded) the ends (corners) are enlarged to increase the distance “d” between re-grown region and active region to minimize the leakage in corner regions.

Increasing “d” at the corners is intended to reduce corner effects and allow edge effects to dominate. Just having bigger ends could achieve this purpose, which could be accomplished (for example) with big square ends, but there could still be large defects that are longer than “d”. Rounded corners (or, substantially round, as illustrated by the octagonal ends) eliminates the sharp corners completely, therefore may be more effective than only increasing “d”.

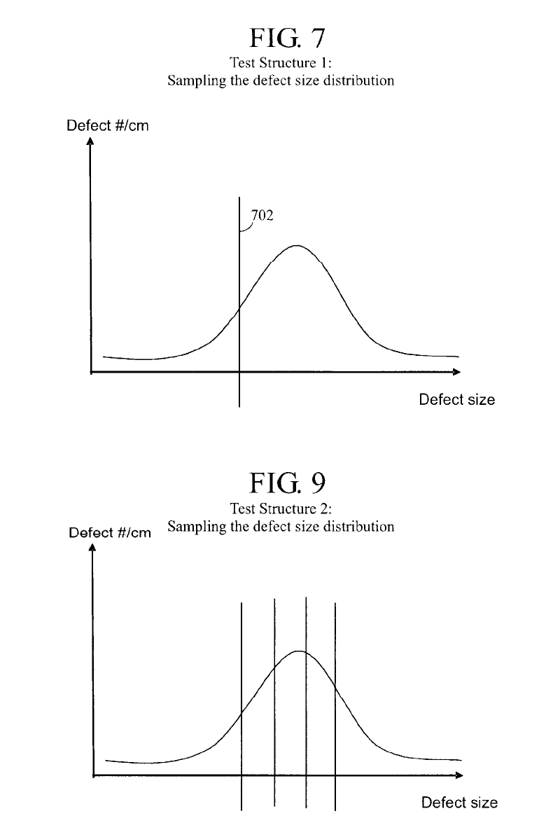

The distance between “d” the active edge and the re-grown region edge is the same everywhere. Because only defects extending into the active region will cause gate leakage, this structure is only sensitive to defects with an “effective size” larger than this designed distance “d”. Here, effective size is defined as the size of the defects along the direction that is perpendicular to the edge of the re-grown region and active area. Therefore, as illustrated in the graph of FIG. 7, the dog-bone shaped test structure is sampling the defect size distribution to the right of the line 702 in FIG. 7 defined by design distance between active region edge and re-grown region edge. If multiple structures with varying distance between active and re-grown region edges were to be placed on the wafer (as discussed below, with reference to “tower-shaped” test structures, these structures together would provide sampling along different locations on the defect size distribution curve, as illustrated in the graph of FIG. 9.

An additional feature of the dog-bone shaped test structure is that it allows the separation of gate leakage caused by edge defects and corner defects.

FIG. 5 is a cross-sectional view of the test structure 400 of FIG. 4A, taken on a line 5-5 through FIG. 4A. Gate oxide (407) is shown disposed between the active region (406) and the polysilicon (408).

Some additional (and conventional) features which are shown in FIG. 5 (and which are not shown in FIG. 4A, for illustrative clarity) are:
insulating material separates the two different crystalline regions during EPI growth; and
shallow trench isolation (STI).

FIG. 4A shows a structure with an elongate active region 406 disposed within an elongate re-grown region, with a substantially uniform design distance “d” between edges of the active region and the re-grown region, to detect gate leakage caused by EPI edge defects, and has been discussed hereinabove.

A reference (control) structure is shown in FIG. 4B, which has no re-grown region (404) at all, and can be used, in conjunction with the results obtained from the test structure of FIG. 4A, to determine the effect of HOT edge defects.

For example, considering there is another mechanism “A” that can cause gate leakage, and “A” has nothing to do with HOT (re-grown region). Assuming that there are 100 test structures of FIG. 4A and 100 structures of FIG. 4B, and there are Na and Nb failures each. It can then reasonable be inferred that all Nb failures of FIG. 4B type of structures are caused by mechanism “A”, similarly Nb failures of FIG. 4A type of structures are also caused by mechanism “A”, and (Na—Nb) failures of FIG. 4A type of structures are caused by HOT edge defects.

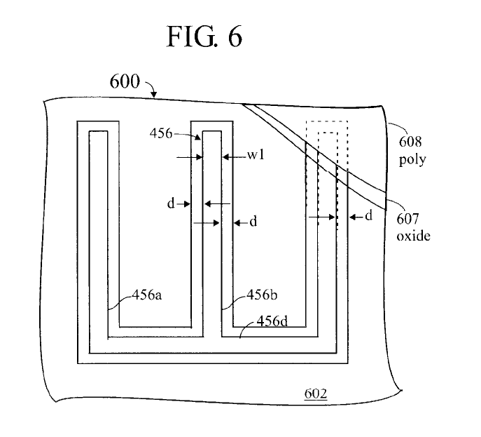

FIG. 6 shows another test structure 600 (compare 400) which is intended to detect impact from HOT corner defects. Generally, the structure is the same as shown in FIG. 4A, but without the corner treatment (enlarged, rounded dog-bone ends of the re-grown region 404) to reduce corner effects. (From another perspective, the test structure 600 of FIG. 6 is similar to the control structure 450 of FIG.4B, with the addition of a re-grown region symmetrically surrounding the active region.) Therefore, it will be sensitive to both edge defects and corner defects.

The test structure 600 (compare 400) of FIG. 6 (compare FIG. 4A) comprises:
a substrate 602 (compare 402);
a re-grown region 604 (compare 404) on the substrate;
an active region 606 (compare 406) in the re-grown region;
a layer of oxide 607 (compare 407); and
a layer of poly 608 (compare 408) disposed atop the test structure.

The test structure 600 does not have the dog-bone corner treatment, so that it will be sensitive to both edge and corner defects. (The FIG. 4A dog-bone shaped test structure is designed to minimize corner effects.) By comparison between the measurements of structures in FIG. 4A and FIG. 6, the impact due to corner-intensive HOT defects can be separately detected.

Generally, in the FIG. 6 test structure, the relevant dimensions for the active region 606 and the re-grown region 604 may (should) be the same as in either of FIGS. 4A and 4B, and the design distance “d” may be the same.

Generally, in FIGS. 4A, 4B and 6, all of the elements are drawn substantially to scale with one another, and dimensional relationship which are not specifically discussed or labeled may be inferred from these drawings.

FIG. 7, mentioned above, illustrates sampling the defect size distribution for test structure 1, the dog-bone shaped test structure of FIG. 4A. It should be noted that:
This test structure should only be sensitive to defect size bigger than EPI-RX spacing “d”; assuming a normal distribution of defect size, it is sampling the right side of a normal distribution.
Critical length can be calculated from design, and yield can be predicted using assumed defect size distribution (DSD).
By designing structures with various spacings, and measuring their actual yield, DSD (or parameters that determines DSD) can be back-solved.

### Test Structure 2: Tower-Shaped Test Structure:

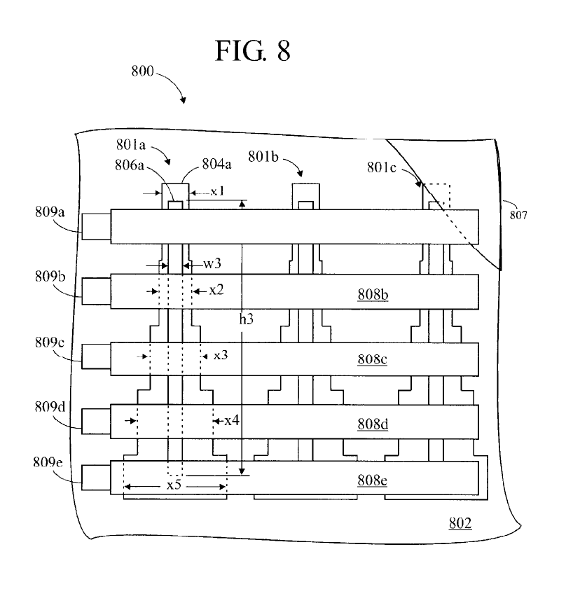

The dog-bone shaped test structure has a uniform (certain, fixed) distance “d” between re-grown and active regions, and is sensitive to defects with sizes above this designed distance “d”. In order to sample different locations in the defect size “X” distribution (see FIG. 3), multiple structures with different distance between re-grown and active regions would ordinarily need to be placed across the wafer and measured. However, having several discrete multiple structures can lead to inaccurate results when coupled with naturally-occurring across-chip and across-wafer process variations in such parameters such as silicon re-grow rate, gate oxide thickness, and active dimensions. In order to reduce or eliminate such undesirable couplings, a tower-shaped test structure is designed as shown in FIG. 8.

As used herein, “tower shaped” means an elongate structure having a length substantially greater than its width (such as at least 4 or 5 times greater) and two opposite ends. The width of the structure increases in increments, stepwise, from a minimum width at one end to a maximum width at the opposite end. One might also characterize this as a “wedding cake” structure. Of course, as with the dog-bone shaped structure, the tower (or wedding cake) shaped structure is only a 2-dimensional representation of its real world, 3-dimensional analogue.

Generally, the tower shaped test structure has height and width approximately equal to the height and width of the dog-bone shaped test structure, the primary differences being that the tower shaped test structure does not have enlarged ends, and the re-grown region is varied in width, stepwise (x1 . . . x5), resulting in a like number of design distances “d1 . . . d5” for measuring edge defects. Also, there is a separate poly for each different width (and different design distance) portion of the test structure.

FIG. 8 shows a test structure 800 comprising three, side-by-side tower-shaped structures 801a, 802b, 801c, on a substrate 802 (compare 402). The three structures 801a, 801b, 801c are similar (and may be identical) to one another.

The structure 801a comprises an elongate re-grown region 804a and an elongate active region 806a. The structure 801b comprises an elongate re-grown region 804b and an elongate active region 806b. The structure 801c comprises an elongate re-grown region 804c and an elongate active region 806c.

The three elongate active regions 806a, 806b, 806c (compare 406a, 406b, 406c) may be joined at one end by a fourth active region 806d (compare 406d).

Generally, the purpose of this tower-shaped test structure is to test different sizes of defects, rather than corner defects.

One structure 801a will be described in detail, as representative of the other two structures 801b and 801c.

An elongate active region 806a is shown, and is generally rectangular, having a width w3 (compare w1, FIG. 4B) and a height h3 (compare h1, FIG. 4B). The height should be at least 4 or 5 times the width, because different portions of the active region serve distinct purposes.

The active region 806a is shown disposed symmetrically (centered transversely) within a larger (previously formed) within a re-grown region 804a (compare 404) which is longer and wider than the active region 806a, as follows.

The re-grown region 804a has a width (x) which is increased in stepwise fashion,

from a smallest width (x1) at a first portion of the re-grown region 804a,

to a larger width (x2) at a second portion of the re-grown region 804a,

to a larger width (x3) at a third portion of the re-grown region 804a,

to a larger width (x4) at a fourth portion of the re-grown region 804a,

to a largest width (x5) at a fifth portion of the re-grown region 804a.

The active region 806a is centered transversely within the re-grown region 804a, and has an exemplary width (w3) of 100 nm. The various portions of the re-grown region 804a, may have the following widths,

x1, 200 nm

x2, 250 nm

x3, 300 nm

x4, 350 nm

x5, 400 nm

The design distance “d”, is defined as the distance between the edge of the active region 806a (compare 406) and the re-grown region 804a (compare 404). Since there are n=5 different widths (xn) for the re-grown region 804a, but only one width (w3) for the active region 806a, a set of “n” design distances can readily be calculated, as follows, dn=(xn-w3)/2. For example,

a first design distance d1 is 100 nm

a second design distance d2 is 150 nm

a third first design distance d3 is 200 nm

a fourth design distance d4 is 250 nm

a fifth design distance d5 is 300 nm

There is a separate poly conductor (generally 808, compare 408) for each of the distinct width portions of the re-grown region, so that separate defect measurements may be taken, and each poly conductor (generally 808) is associated with a respective pad (generally 809) for a test instrument (not shown) to make contact and take measurements.

More particularly,

a first poly line 808a extends across the active region 806a in the smallest width (x1) first portion of the re-grown region 804a, and terminates in a pad 809a;

a second poly line 808b extends across the active region 806a in the next larger width (x2) second portion of the re-grown region 804a, and terminates in a pad 809b;

a third poly line 808c extends across the active region 806a in the next larger width (x3) third portion of the re-grown region 804a, and terminates in a pad 809c;

a fourth poly line 808d extends across the active region 806a in the next larger width (x4) fourth portion of the re-grown region 804a, and terminates in a pad 809d;

a fifth poly line 808e extends across the active region 806a in the largest width (x5) fifth portion of the re-grown region 804a, and terminates in a pad 809e.

An oxide layer 407 (shown partially, for illustrative clarity: compare 407) is disposed over the surface of the substrate 402, between the active regions 804 and the poly structures 808, so that the test structure 400 can function analogous to an FET, and be used to measure gate oxide leakage resulting from edge defects.

Each portion of the structure has a separate poly conductor 808a, 808b, 808c, 808d, 808d (generally, 808) connected to a corresponding contact pad 809a, 809b, 809c, 809d, 809e (generally 809), which allows the gate leakage to be measured separately. Gate oxide (not shown, see FIG. 5) is disposed between the active region 806 and the poly 808. The poly (808) in this and in the previous examples (408, 458, 608) simulates a gate of an FET.

This same tower 801a is repeated from left-to-right (as shown) to increase the perimeter of re-grown region edges thus increasing defect capturing. Each pad (generally 809) is used to detect certain size of edge defects (with different EPI-RX spacing).

An advantage of a tower structure is that all of the different sizes are in the same structure and in the same EPI to allow side-by-side comparison, while substantially reducing or eliminating undesirable couplings.

This structure has the advantage of sampling multiple locations on the defect size distribution within the same structure, as shown in the graph of FIG. 9. Since the different portions under test share a single (the same whole) piece of re-grown region and active region, it provides a fair side-by-side comparison among HOT defects of various sizes.

Advantages of the tower-shaped test structure include,
edge defect size distribution can be measured in one structure instead of multiple structures, to avoid structure-to-structure variations
EPI is continuously the same piece
RX is continuously the same piece
no rounding/cornering of EPI and RX—remove corner impact

In the tower shaped test structure, each pad is used to detect certain sizes of edge defects. Advantages of this test structure include, all sizes are in the same structure and same re-grown region to allow side-by-side comparison.

As was discussed with respect to the dog-bone test structure, a non-HOT version of the tower test structure can be implemented to subtract out normal leakages.

FIG. 9 relates to test structure 2, the tower-shaped test structure of FIG. 8. It should be noted that:
measures edge defect size distribution in one structure instead of multiple structures, to avoid structure-to-structure variations.
EPI is continuously same piece
RX is continuously same piece
no rounding/cornering of EPI and RX—remove corner impact.

### Test Structure 3: Inside-Hole Shaped Test Structure:

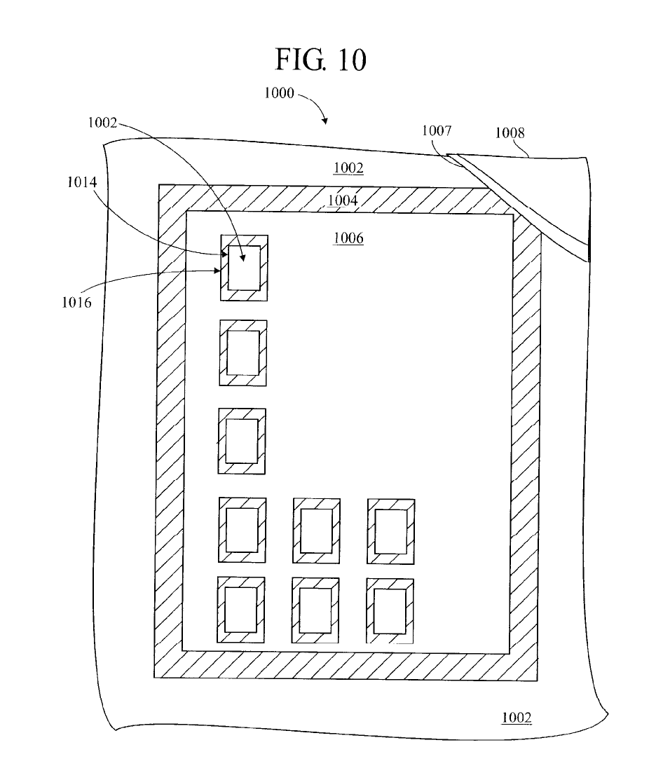

The dog-bone shaped and tower-shaped structures described hereinabove both use gate leakage to detect HOT defects. However, HOT defects is also expected to cause junction leakage of a PN junction. In order to detect and quantify the junction leakage caused by HOT defects, an inside-hole shaped test structure is provided, as shown in FIG. 10.

FIG. 10 shows an inside-hole test structure 1000 formed on a substrate 1002, which is original silicon (non-HOT).

A large pad of re-grown region 1004 (compare 804) is formed—for example, the re-grown region is rectangular, measuring for example 105×105 μm. In a typical HOT process, the re-grown region serves as the substrate, and may be N-well. The re-grown region 1004 is shown with shading (cross-hatching) for illustrative clarity, but it should be understood that FIG. 10 is not a cross-section, but rather a plan, top view.

The re-grown region 1004 is formed with a plurality of openings (“inside holes”) 1014, within which is original, non-HOT silicon 1002. These holes 1014 may measure approximately 200×200 nm.

A large active P+ region 1006 (compare 806) is formed within the re-grown region 1004, and may also be rectangular, measuring for example approximately 100×100 μm, or slightly smaller than the re-grown region 1004, and generally centered within the re-grown region 1004.

The active region 1006 is formed with a plurality of openings (windows) 1016, slightly larger than and centered about the openings 1014, exposing “frames” of underlying re-grown region 1004, as illustrated. The openings 1016 may be rectangular or square. Their exact size is dependent on the specific technology and design requirements—for example, approximately 200×200 nm.

The re-grown region 1004 and the active region 1006 are whole pieces (i.e., continuous conducting by themselves, although they have openings in them) to minimize series resistance during the measurements of junction leakage current. The smaller original silicon regions within the openings 1014 may be rectangular, measuring for example approximately 100×100 nm.

A layer of oxide 1007 (shown partial, for illustrative clarity) is covered by a layer of poly 1008, which is connected (not shown) to an external test instrument (not shown).

The openings 1016 in the active region 1006 are substantially centered within the openings 1014 in the re-grown region 1004.

Junction leakage between the N-well 1004 and the P+ active region 1006 may be measured with this inside-hole test structure 1000. If there is any defect originating from the edge, including inside edge, of the re-grown region and extending into the active region, it will cause junction leakage and therefore be detected.

In general, it is believed that a reference structure corresponding to this test structure is no required, because a reference structure should almost never fail in this case.

A reason for this inside-hole design is that junction leakage is typically very small. In order to detect such small current, the series resistance along the current path, especially the portion of the current path in the substrate must be minimized. In this design, since the whole piece of N-well substrate and P+ active serve as the current path, the series resistance is effectively minimized. Note that the distance between the re-grown region and the active region is the same across this structure. Therefore it is sampling defect sizes above this designed distance, as previously shown in FIG. 7.

Advantages of this inside-hole shaped test structure include,
besides gate leakage, junction leakage may also be sensitive to EPI edge defects; EPI edge defects cause high junction leakage.
inside holes in EPI/Nwell region are used to maximize the RX-EPI interface perimeter
EPI/Nwell is a big whole piece to minimize series resistance for junction leakage current measurement.

While the invention has been described with respect to a limited number of embodiments, these should not be construed as limitations on the scope of the invention, but rather as examples of some of the embodiments. Those skilled in the art may envision other possible variations, modifications, and implementations that are also within the scope of the invention, based on the disclosure set forth herein.

1. A method for detecting defects arising from hybrid orientation technology (HOT) comprising:
measuring defect size and location in terms of device leakage;
selecting the device leakage from the group consisting of gate leakage, junction leakage, and sub-threshold leakage;
calculating hybrid orientation technology (HOT) edge defect density and edge defect size distribution;
using the resulting defect information to calibrate a defect yield model;
said method further comprising the steps of:
fabricating a test structure for detecting edge defects in a HOT semiconductor substrate;
selecting a dog-bone shaped test structure to facilitate separation of the effects of defects originating from the edge and corner of an elongated re-grown region;
disposing an elongate active region in the elongated re-grown region, the re-grown region having a width that increases in increments, stepwise, from a minimum width at one end of the re-grown region to a maximum width at the opposite end of the re-grown region;
providing an overlying poly layer over the elongated active region;
disposing oxide between the overlying poly layer and the elongated active region;
providing a distance (d) between an edge of the elongated active region and an edge of the re-grown region that is substantially uniform along an edge of the test structure; and
providing inside holes within the test structures that can detect detects junction leakage induced by HOT defects while reducing the series resistance of the current path.

2.-20. (canceled)
